(19) United States
(12) Patent Application Publication
(10) Pub. No.: US 2008/0217716 A1
(43) Pub. Date: Sep. 11, 2008

(54) Imaging apparatus, method, and system having reduced dark current

(76) Inventor: Richard A. Mauritzson, Meridian, ID (US)

Correspondence Address: DICKSTEIN SHAPIRO LLP, 1825 EYE STREET NW, Washington, DC, 20006-5403, US

(21) Appl. No.: 11/715,885

(22) Filed: Mar. 9, 2007

(51) Int. Cl. H01L 31/00

(52) U.S. Cl. 257/443

(57) ABSTRACT

An imaging method, apparatus, and system having an image sensor having a p-type substrate to getter metallics and other contaminants, an n-type epitaxial layer arranged on the p-type substrate to reduce dark current, cross-talk, and blooming, and a p-type epitaxial layer arranged on the n-type epitaxial layer.

### FIELD OF THE INVENTION

Embodiments of the invention relate to imaging devices having reduced dark current and reduced electrical cross-talk.

### BACKGROUND OF THE INVENTION

A CMOS imaging device circuit includes a focal plane array of pixels, each one of the pixels including a photosensor, for example, a photogate, photoconductor or a photodiode overlying a substrate for accumulating photo-generated charge in the underlying portion of the substrate. Each pixel has a readout circuit that includes at least an output field effect transistor formed in the substrate and a charge storage region formed on the substrate connected to the gate of an output transistor. The charge storage region may be constructed as a floating diffusion region. Each pixel may include at least one electronic device such as a transistor for transferring charge from the photosensor to the storage region and one device, also typically a transistor, for resetting the storage region to a predetermined charge level prior to charge transference.

In a CMOS imaging device, the active elements of a pixel perform the necessary functions of: (1) photon to charge conversion; (2) accumulation of image charge; (3) resetting the storage region to a known state before the transfer of charge to it; (4) transfer of charge to the storage region accompanied by charge amplification; (5) selection of a pixel for readout; and (6) output and amplification of a signal representing pixel charge. Photo charge may be amplified when it moves from the initial charge accumulation region to the storage region. The charge at the storage region is typically converted to a pixel output voltage by a source follower output transistor.

FIG. 1 shows a top view of a conventional individual four-transistor (4T) pixel 10 of a CMOS image sensor 100 (FIG. 2). Pixel 10 generally comprises a transfer gate 50 for transferring photoelectric charges generated in a photosensor 21, which may be a pinned photodiode 21, to a floating diffusion region FD acting as a sensing node, which is in turn, electrically connected to the gate 60 of an output source follower transistor. A reset gate 40 is provided for resetting the floating diffusion region FD to a predetermined voltage, and a row select gate 80 is provided for outputting a signal from the source follower transistor to an output terminal in response to a pixel row select signal on row select gate 80. The source follower and row select transistors are coupled to each other via their common source/drain region 22 and the pixel 10 is coupled to other elements of the imaging device via the contacts 32.

CMOS imaging devices of the type discussed above are generally known as discussed, for example, in U.S. Pat. No. 6,140,630, U.S. Pat. No. 6,376,868, U.S. Pat. No. 6,310,366, U.S. Pat. No. 6,326,652, and U.S. Pat. No. 6,204,524 assigned to Micron Technology, Inc., which are hereby incorporated by reference in their entirety.

Signals generated in an imaging device by a process other than incident light impinging on a pixel's respective photosensor 21 is generally called dark current. Dark current is undesirable because it alters the correct capture of an image and can increase the signal representing pixel charge from an individual pixel, which can result in a saturated or bright spot in the output image even when incident light might not otherwise saturate a pixel. Dark current can be generated by silicon surface states, silicon dislocation or metallic contamination, and is aggravated by higher temperatures.

Another source of dark current is charge leaked from peripheral circuits located on the same substrate as the pixel array into pixels of the pixel array. It is therefore desirable to isolate the peripheral circuits from one another and from the pixel array.

Another phenomenon that can negatively affect image quality is electrical cross-talk. Electrical cross-talk occurs when current is leaked from a charge collection region of one photosensor into another pixel. If the incident light captured and converted into a charge by a photosensor during an integration period is greater than the capacity of the photosensor, excess charge may overflow and be transferred to adjacent pixels. This type of electrical cross-talk is known as blooming.

Conventional CMOS imaging devices have attempted to isolate pixels to reduce dark current and cross-talk using various isolation regions. FIG. 2, illustrates a top view of a CMOS image sensor indicated generally by reference numeral 100. Image sensor 100 comprises a peripheral substrate region 180 and a pixel array substrate region 170. Field oxide regions 190 are used to isolate individual pixels 10 as well as to isolate circuits in the peripheral substrate region 180 from the pixel array substrate region 170. An n-type sidewall or guard-ring 140 may also be used to form an n-type region isolation structure which separates the pixel array region 170 from the peripheral circuit region 180 as described in U.S. Patent Application Publication no. 2005/0133825, assigned to Micron Technology, Inc., which is hereby incorporated by reference in its entirety.

FIG. 3 shows a cross-section view of the CMOS image sensor 100. The image sensor 100 includes an n− or n+ type substrate 130, an optional n-epitaxial layer 120 arranged on the substrate 130, and a p-epitaxial layer 110 arranged on the n-epitaxial layer 120. The n-epitaxial layer 120 and n-type substrate 130 help prevent electron leakage from circuits on the peripheral substrate region 180, and cross-talk from adjacent pixels due to blooming or stray photo-generated electrons in the p-epitaxial layer 110.

As mentioned above, dark current may be caused by metallics and other contaminants that become trapped in the imaging device during fabrication and may migrate freely between the substrate 130, the p− layer 110, and the n− isolation layer 120 during fabrication. If the metal atoms or other contaminants become trapped in the p− layer they may generate dark current, which may interfere with the charge collection by the pixel photosensors 21.

Therefore, a need exists for an imaging device that can reduce cross-talk, blooming, and dark current generated from these various sources.

### BRIEF DESCRIPTION OF THE DRAWINGS

FIG. 1 is a top down view of a conventional pixel of a CMOS image sensor.

FIG. 2 is a top down view of a conventional CMOS image sensor.

FIG. 3 is a fragmentary sectional view of a section of the CMOS image sensor of FIG. 2.

FIG. 4 is a fragmentary sectional view of the CMOS image sensor in accordance with a described embodiment.

FIG. 5 is a top down view of a CMOS image sensor in accordance with a described embodiment.

FIG. 6 is a fragmentary sectional view of the CMOS image sensor in accordance of FIG. 4 in operation.

FIG. 7 illustrates a pixel array suitable for use with any of the embodiments described herein.

FIG. 8 illustrates a system suitable for use with any of the embodiments described herein.

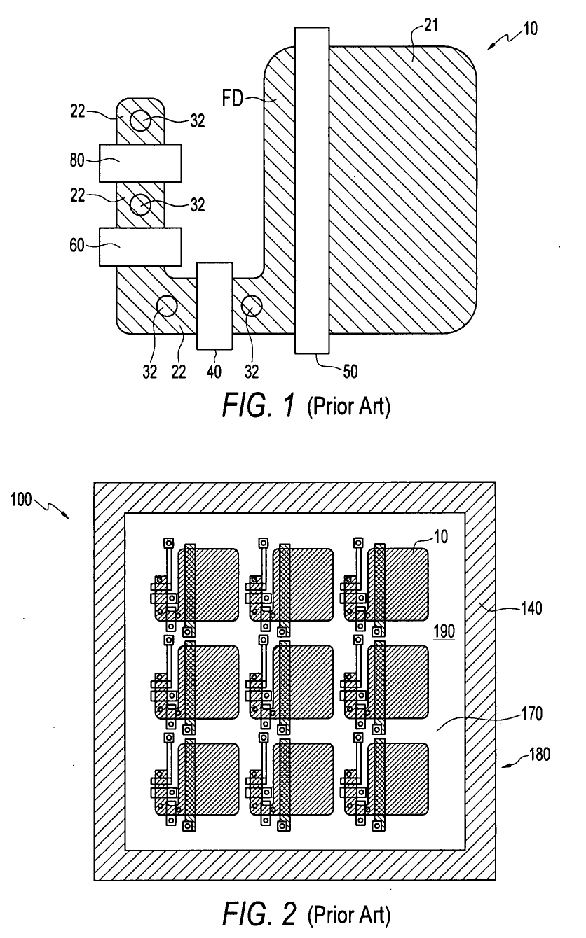

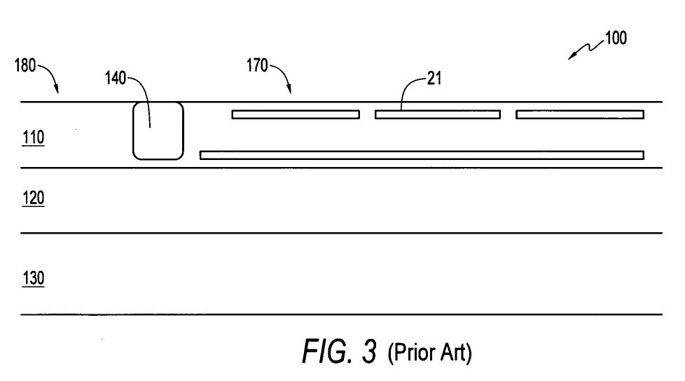

### DETAILED DESCRIPTION

In the following detailed description, reference is made to the accompanying drawings, which form a part hereof, and in which is shown by way of illustration specific embodiments of the invention. These embodiments are described in sufficient detail to enable those skilled in the art to practice the invention, and it is to be understood that other embodiments may be utilized, and that structural, logical and electrical changes may be made without departing from the spirit and scope of the invention.

The term “substrate” is to be understood as including silicon, silicon-on-insulator (SOI), or silicon-on-sapphire (SOS) technology, doped and undoped semiconductors, epitaxial layers of silicon supported by a base semiconductor foundation, and other semiconductor structures. Furthermore, when reference is made to a “substrate” in the following description, previous process steps may have been utilized to form regions or junctions in the base semiconductor structure or foundation. In addition, the semiconductor need not be silicon-based, but could be based on other semiconductors including silicon-germanium, germanium, or gallium-arsenide. The term “pixel” refers to a picture element unit cell containing a photosensor.

One embodiment provides an imaging device formed on a p+ substrate. A p+ substrate acts to getter or trap metal atoms or other contaminants entering into an imaging device during fabrication. As metal atoms or contaminants migrate through the layers of the imaging device, they may become trapped, i.e. gettered, in the p+ substrate, where they will generate little or no dark current. This provides a benefit over a conventional imaging devices using an n-type substrate because n-type substrates are not as effective at gettering metallics and other contaminants as p-type substrates, and therefore metallics and contaminants may migrate throughout the imaging device and become lodged in the upper layers where they may generate dark current.

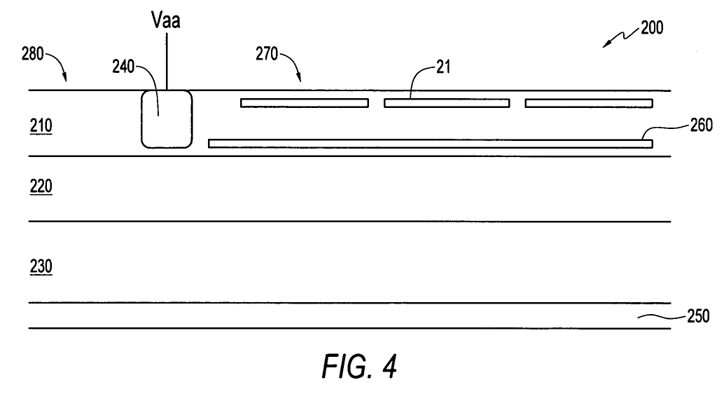

FIG. 4 shows an embodiment of a cross-section view of a CMOS image sensor 200. The image sensor 200 includes an p+ substrate 230. The p+ substrate 230 acts to getter metallics and other contaminants that may enter the image sensor during fabrication. In one embodiment, the p+ substrate 230 may be doped to a resistivity of about 0.001 to about 0.05 Ω-cm. In another embodiment, the p+ substrate may be doped to a resistivity of about 0.01 Ω-cm.

An n− epitaxial layer 220 may be arranged on the p+ substrate 230. The n− epitaxial layer 220 helps prevents charge interference from circuits on the peripheral substrate region 280 and from adjacent or nearby pixels 21 in the pixel array and also reduces blooming by collecting excess electrons from pixels in the array during overexposure conditions. The n− epitaxial layer 220 may be about 2 to about 6 μm thick and may be doped to a resistivity of about 10 to about 25 Ω-cm.

A p− epitaxial layer 210 may be arranged on the n− epitaxial layer 220. The p− epitaxial layer 210 may be about 2 to about 8 μm thick and may be doped to a resistivity of about 10 to about 25 Ω-cm. The n-type doped regions forming the photodiodes 21 of the pixels 10 may be arranged in the p− epitaxial layer 210.

A polysilicon backing 250 may optionally be arranged under the p+ type substrate 230. The polysilicon backing 250 may also getter metallics and contaminants.

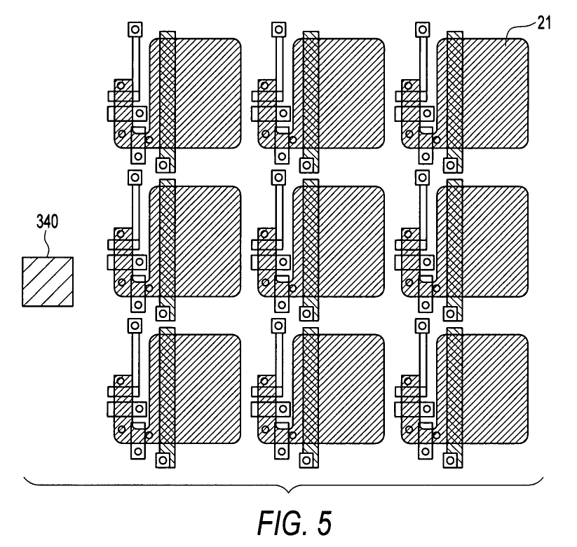

An n-type sidewall, guard-ring, or series of contacts 240 may optionally be arranged in the p− epitaxial layer 210 to form an n-type region isolation structure that separates the pixel array region 270 from the peripheral circuit region 280 to block current. The n-type sidewall 240 may completely surround the pixel array region 270, or may be arranged only along one or more sides of the pixel array region 270. The n-type sidewall provides a means to apply voltage to the n-epitaxial layer 220. In CMOS image sensor 300 shown in FIG. 5, the n-type sidewall 240 is replaced with an n-type well region 340. The electrical connection between the n-type well region 340 and the n-epitaxial layer 220 may be made with any n-type connection and does not have to be located in the pixel array region 270.

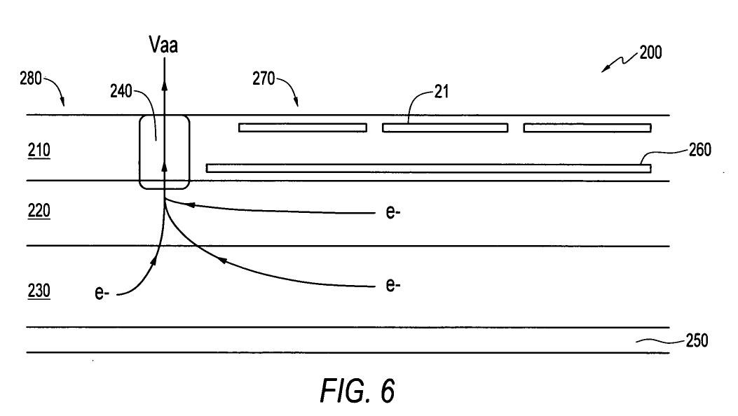

FIG. 6 is a cross-section view of the CMOS image sensor 200 of FIG. 4 with a positive voltage applied to the sidewall 240. The sidewall 240 may be physically connected to the n-epitaxial layer. Alternatively, if sidewall 240 is not physically connected to the n-epitaxial layer 220, it may be biased with a positive voltage so that its depletion layer expands to make an electrical connection with the n− epitaxial layer 220 to draw electrons generated by dark current, blooming, or crosstalk out of the isolation layer 220 and the substrate 230. A p+ isolation implant region 260 may be formed in the p− epitaxial layer 210 near the n−/p− interface of the p− epitaxial layer 210 and the n− epitaxial layer 220 of the pixel array substrate region 270 to reduce the upward depletion region of the n− epitaxial layer 220 and prevent it from drawing electrons from charge storage areas within the pixels 10.

The image sensor 200 may be formed by doping a substrate to the appropriate concentration to form the p+ type substrate 230. Next, the n− epitaxial layer 220 may be grown on the p+ type substrate 230, and the p− epitaxial layer 210 may be grown on the n− epitaxial layer 220. Growing the n− epitaxial layer 220 is advantageous because it allows the n− epitaxial layer 220 to be farther from the surface of the p− epitaxial layer 210 than could be achieved by implanting an n− layer. The n-type sidewall 240, the p+ isolation implant region 260, and the photosensors 21 may be fabricated in the p− epitaxial layer 210.

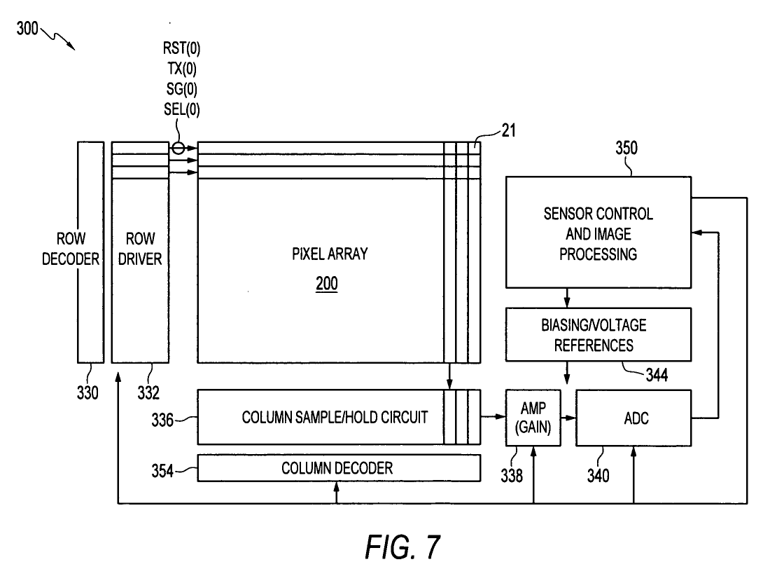

FIG. 7 illustrates a CMOS imager 300 that may incorporate the disclosed embodiments. The illustrated imager 300 includes an image sensor 200 comprising a plurality of pixels 10 arranged in a predetermined number of rows and columns. A plurality of row and column lines are provided for the image sensor 200. The row lines e.g., SEL(0) are selectively activated by row decoder 330 and driver circuitry 332 in response to an applied row address. Column select lines (not shown) are selectively activated in response to an applied column address by column circuitry that includes column decoder 354. Thus, row and column addresses are provided for each pixel 21. The CMOS imager 300 is operated by a sensor control and image processing circuit 350, which controls the row and column circuitry for selecting the appropriate row and column lines for pixel readout.

Each column is connected to sampling capacitors and switches in the sample and hold circuitry 336. A pixel reset signal Vrst, which is taken after the floating diffusion region FD is reset by the reset transistor, and a pixel image signal Vsig, which is taken after charge is transferred by transfer gate 50 to the floating diffusion region FD, for selected pixels are sampled and held by the sample and hold circuitry 336. A differential signal (Vrst-Vsig) is produced for each readout pixel by the differential amplifier 338 (AMP), which applies a gain to the signal received from the sample and hold circuitry 336. The differential signal is digitized by an analog-to-digital converter 340 (ADC). The analog-to-digital converter 340 supplies the digitized pixel signals to the sensor control and image processing circuit 350, which among other things, forms a digital image output. The imager also contains biasing/voltage reference circuitry 344.

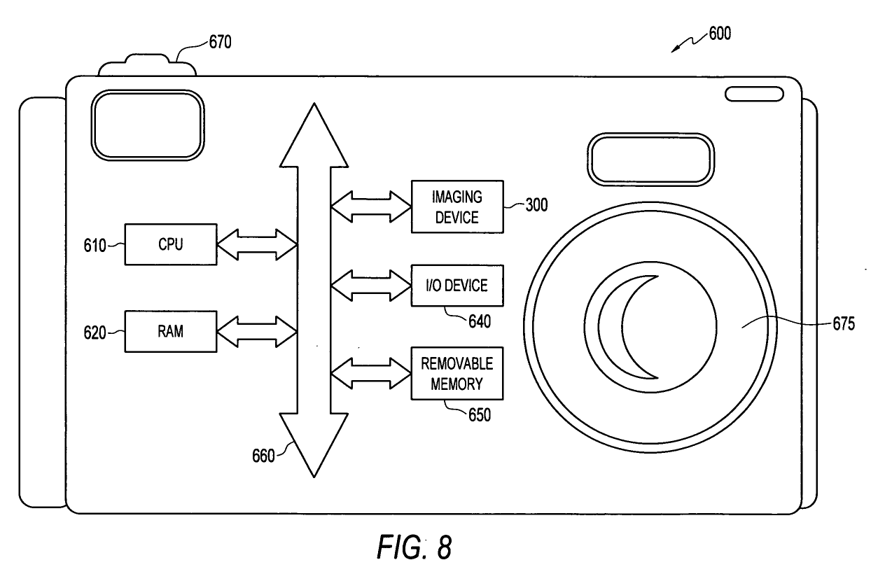

FIG. 8 shows a processor system 600, for example, a digital camera system, which includes an imaging device 300 constructed to include an image sensor 200 arranged and operated in accordance with an embodiment described herein. The processor system 600 is an example of a system having digital circuits that could include imaging devices. Without being limiting, in addition to a digital camera system, such a system could include a computer system, scanner, machine vision system, vehicle navigation system, video phone, surveillance system, auto focus system, star tracker system, motion detection system, image stabilization system, and other processing systems employing an imaging device 300.

System 600, for example a camera system, generally comprises a central processing unit (CPU) 610, such as a microprocessor, that communicates with an input/output (I/O) device 640 over a bus 660. Imaging device 200 also communicates with the CPU 610 over the bus 660. The system 600 also includes random access memory (RAM) 620, and can include removable memory 650, such as flash memory, which also communicate with the CPU 610 over the bus 660. Imaging device 200 may be combined with a processor, such as a CPU 610, digital signal processor, or microprocessor, in a single integrated circuit. In a camera application, a shutter release button 670 is used to operate a mechanical or electronic shutter to allow image light which passes through a lens 675 to be captured by the imaging device 300.

The processes and devices described above illustrate preferred methods and typical devices of many that could be used and produced. The above description and drawings illustrate embodiments, which achieve the objects, features, and advantages described herein. However, it is not intended that the embodiments be strictly limited to the described and illustrated embodiments. For example, although various embodiments described herein have been described with specific reference to CMOS imaging circuits having a photodiode, the invention has broader applicability and may be used in other imaging apparatus to reduce dark current. For example, the invention also applies to charge-coupled devices (CCD's) and other imaging technologies.

What is claimed as new and desired to be protected by Letters Patent of the United States is:

1. An imaging device, comprising:
a p-type substrate;
an n-type epitaxial arranged on substantially the entire p-type substrate;
a p-type epitaxial arranged on the n-epitaxial; and
a plurality of pixel circuits arranged in a pixel array region of the p-type epitaxial.

2. The imaging device of claim 1, wherein the p-type substrate is a p+ substrate.

3. The imaging device of claim 1, wherein the n-type epitaxial is an n− epitaxial.

4. The imaging device of claim 1, wherein the p-type epitaxial is a p− epitaxial.

5. The imaging device of claim 1, further comprising a polysilicon arranged under the p-type substrate.

6. The imaging device of claim 1, further comprising an n-type doped region arranged in the p-type epitaxial and coupled to a positive voltage source terminal for drawing electrons out of the n− epitaxial.

7. The imaging device of claim 1, further comprising a p-type isolation implant region arranged in the p-type epitaxial and under the pixel array region.

8. The imaging device of claim 1, further comprising an n-type doped region arranged in the p-type epitaxial and surrounding the pixel array region.

9. The imaging device of claim 8, wherein the n-type doped region is coupled to a positive voltage source terminal for drawing electrons out of the n− epitaxial.

10. The imaging device of claim 1, wherein the p-type substrate is doped to a resistivity of about 0.001 to about 0.05 Ω-cm.

11. The imaging device of claim 1, wherein at least one of the p-epitaxial or n-epitaxial is doped to a resistivity of between about 10 to about 25 Ω-cm.

12. (canceled)

13. The imaging device of claim 1, wherein the n− epitaxial is between about 2 to about 6 μm thick.

14. The imaging device of claim 1, wherein the p− epitaxial is between about 2 to about 8 μm thick.

15. An imaging device, comprising:
a p-type substrate;
an n-type epitaxial layer arranged on the p-type substrate;
a p-type epitaxial layer arranged on the n-epitaxial layer;
a CMOS pixel array comprising a plurality of pixel circuits arranged in the p-type epitaxial layer; and
a circuit for operating the CMOS pixel array to read out signals from the pixel circuits.

16. The imaging device of claim 15, further comprising a polysilicon layer arranged under the p-type substrate.

17. The imaging device of claim 15, further comprising an n-type doped region arranged in the p-type epitaxial layer and around the pixel array and coupled to a positive voltage source terminal.

18. The imaging device of claim 15, further comprising a p-type isolation implant region arranged in the p-type epitaxial layer and under the pixel array.

19. The imaging device of claim 15, wherein the p-type substrate is doped to a resistivity of about 0.001 to about 0.05 Ω-cm, the p− epitaxial layer is doped to a resistivity of between about 10 to about 25 Ω-cm, and the n− epitaxial layer is doped to a resistivity of between about 10 to about 25 Ω-cm.

20. An imaging device, comprising:
a p-type substrate doped to a resistivity of about 0.001 to about 0.05 Ω-cm;
an n-type epitaxial layer doped to a resistivity of between about 10 to about 25 Ω-cm arranged on substantially the entire p-type substrate;
a p-type epitaxial layer doped to a resistivity of between about 10 to about 25 Ω-cm arranged on the n-epitaxial layer;
a plurality of pixel circuits arranged in a pixel array region of the p-type epitaxial layer;
an n-type doped region arranged in the p-type epitaxial layer and surrounding the pixel array region and coupled to a positive voltage source terminal for drawing electrons out of the n− epitaxial layer; and
a p-type isolation implant region arranged in the p-type epitaxial layer and under the pixel array region.

21. An imaging processing system, comprising:
a processor; and
an imaging device communicating with the processor, the device comprising:
a p+ doped substrate for gettering metallics;
an n− epitaxial layer formed over the p+ doped substrate;
a p− epitaxial layer formed over the n− epitaxial layer;
a pixel array region having a plurality of pixels, the pixels having n-type doped photosensor regions arranged in the p− epitaxial layer; and
a peripheral substrate region outside the pixel array region;
wherein the n− epitaxial layer is on the p+ doped substrate in the pixel array region and in the peripheral substrate region.

22-27. (canceled)

28. A method of making an imaging device, comprising:
doping a substrate to form a p-type doped substrate;
growing an n-type epitaxial layer on substantially the entire p-type doped substrate;
growing a p-type epitaxial layer on the n-type epitaxial layer; and
forming a plurality of pixels in a pixel array region, the pixels having n-type doped photosensor regions arranged in the p− epitaxial layer.

29. The method of claim 28, wherein the p-type doped substrate is a p+ doped substrate, the n-type epitaxial layer is an n− epitaxial layer, and the p-type epitaxial layer is a p− epitaxial layer.

30. The method of claim 28, further comprising affixing a polysilicon layer to the p-type doped substrate.

31. The method of claim 28, further comprising doping the p-type epitaxial layer to form a p-type isolation implant region under the pixel array region.

32. The method of claim 28, further comprising doping the p-type epitaxial layer to form an n-type doped region around said plurality of pixels and coupling the n-type doped region to a positive voltage source terminal.

33. (canceled)

34. The imaging device of claim 1, wherein the imaging device is included in a processor system.

35. The imaging device of claim 34, wherein the processor system is a camera.
